(19) United States
(12) Patent Application Publication
(10) Pub. No.: US 2025/0098263 A1
(43) Pub. Date: Mar. 20, 2025

(54) SEMICONDUCTOR DEVICE

(71) Applicant: KABUSHIKI KAISHA TOSHIBA, Tokyo (JP)

(72) Inventors: Tomoaki INOKUCHI, Yokohama (JP); Hiro GANGI, Tokyo (JP); Yusuke KOBAYASHI, Yokohama (JP); Shotaro BABA, Kawasaki (JP); Taichi FUKUDA, Yokohama (JP)

(73) Assignee: KABUSHIKI KAISHA TOSHIBA, Tokyo (JP)

(21) Appl. No.: 18/589,766

(22) Filed: Feb. 28, 2024

(30) Foreign Application Priority Data
Sep. 15, 2023 (JP) 2023-150155

(51) Int. Cl. H01L 29/40; H01L 27/06; H01L 29/06; H01L 29/47; H01L 29/78; H10B 63/00; H10N 70/00

(52) U.S. Cl. CPC H10D 64/117; H10D 62/127; H10D 64/64; H10D 84/146; H10D 84/811; H10B 63/34; H10N 70/826; H10N 70/841

(57) ABSTRACT

A semiconductor device includes a major element including a first semiconductor region, a first electrode, a second electrode, a first gate electrode, and a first insulating member being positioned between the first gate electrode and the first semiconductor region, a gate driver supplying the gate voltage to the first gate electrode, and a recording element electrically connected with the gate driver. The recording element records, as continuously changing analog data, a number of times that the gate voltage is supplied to the first gate electrode while being enough to switch the major element on.

### CROSS-REFERENCE TO RELATED APPLICATION

This application is based upon and claims the benefit of priority from Japanese Patent Application No. 2023-150155, filed on Sep. 15, 2023; the entire contents of which are incorporated herein by reference.

### FIELD

Embodiments described herein relate generally to a semiconductor device.

### BACKGROUND

It is desirable for devices such as, for example, power semiconductor devices to have a prediction function of the life and degradation as the device is used.

### BRIEF DESCRIPTION OF THE DRAWINGS

FIGS. 1A and 1B are schematic views showing a configuration of a semiconductor device of an embodiment;

FIG. 2 is a schematic cross-sectional view of a major element and recording elements of the embodiment;

FIGS. 3 and 4 are schematic perspective views of the major element of the embodiment;

FIG. 5 is a schematic cross-sectional view of the major element of the embodiment;

FIGS. 6A and 6B are schematic perspective views of the major element of the embodiment;

FIG. 7 is a schematic perspective view of the recording element of the embodiment; and

FIGS. 8 and 9 are schematic cross-sectional views of the recording element of the embodiment.

### DETAILED DESCRIPTION

According to one embodiment, a semiconductor device includes a major element including a first semiconductor region, a first electrode, a second electrode, a first gate electrode, and a first insulating member, the first insulating member being positioned between the first gate electrode and the first semiconductor region, a gate voltage of the first gate electrode controlling a current flowing between the first electrode and the second electrode via the first semiconductor region; a gate driver supplying the gate voltage to the first gate electrode; and a recording element electrically connected with the gate driver, the recording element recording, as continuously changing analog data, a number of times that the gate voltage is supplied to the first gate electrode while being enough to switch the major element on.

Embodiments will now be described with reference to the drawings.

The drawings are schematic or conceptual; and the relationships between the thickness and width of portions, the proportions of sizes among portions, etc., are not necessarily the same as the actual values. The dimensions and proportions may be illustrated differently among drawings, even when the same portion is illustrated.

The same or similar components are marked with the same reference numerals.

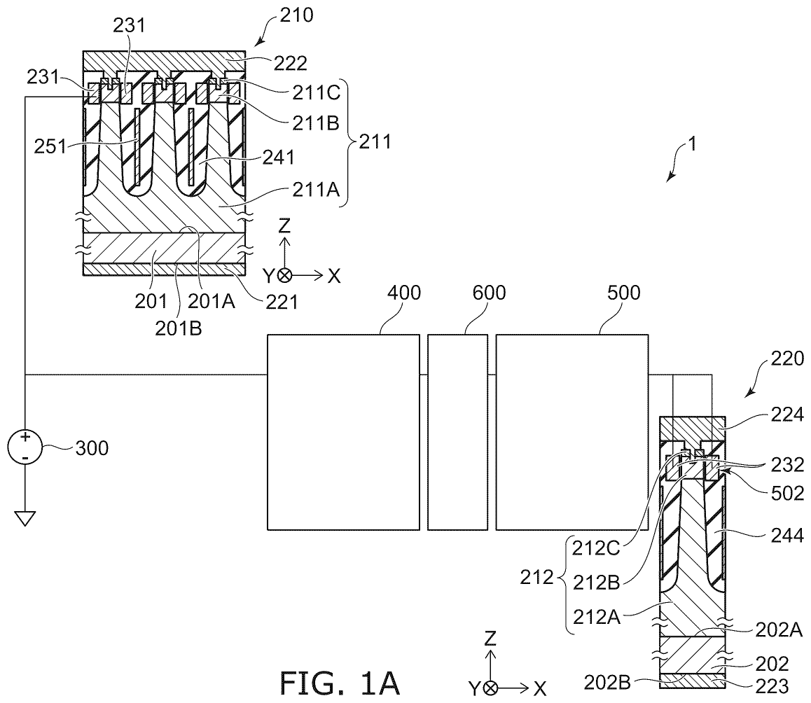

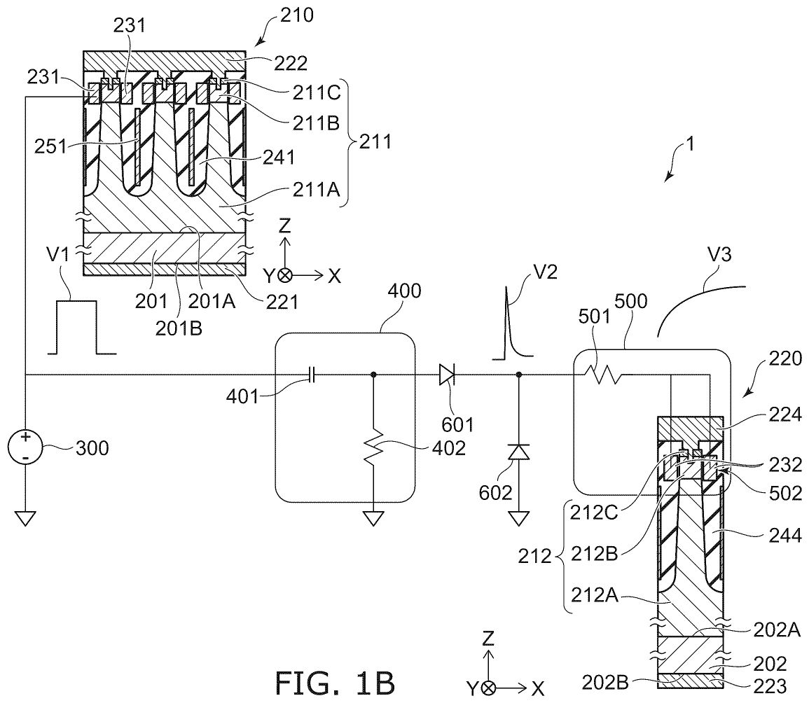

As shown in FIGS. 1A and 1B, a semiconductor device 1 of an embodiment includes a major element 210, a recording element 220, and a gate driver 300. The major element 210 is, for example, a power semiconductor element that controls or converts power. For example, the major element 210 has a vertical MOSFET (Metal-Oxide-Semiconductor Field Effect Transistor) structure.

The major element 210 includes a first semiconductor region 211, a first electrode 221, a second electrode 222, and a first gate electrode 231; and the gate voltage of the first gate electrode 231 controls a current flowing between the first electrode 221 and the second electrode 222 via the first semiconductor region 211.

The major element 210 may further include a substrate 201. The first semiconductor region 211 is located on a first surface 201A of the substrate 201. One direction parallel to the first surface 201A of the substrate 201 is taken as an X-axis direction. A direction parallel to the first surface 201A and perpendicular to the X-axis direction is taken as a Y-axis direction. A direction perpendicular to the X-axis direction and the Y-axis direction is taken as a Z-axis direction. For example, in the major element, a direction along the Y-axis is taken as a first direction Y; a direction along the X-axis is taken as a second direction X; and a direction along the Z-axis is taken as a third direction Z. Along the third direction Z, the direction in which the arrow of the Z-axis is oriented is taken as “above” and the “upper surface side”.

The first semiconductor region 211 includes a first semiconductor part 211A that is located on the first surface 201A of the substrate 201 and is of a first conductivity type, a second semiconductor part 211B that is located on the first semiconductor part 211A and is of a second conductivity type, and a third semiconductor part 211C that is located on the second semiconductor part 211B and is of the first conductivity type. In the specification, for example, the first conductivity type is an n-type; and the second conductivity type is a p-type. The first conductivity type may be the p-type; and the second conductivity type may be the n-type.

For example, the substrate 201 is of the n-type and functions as a drain layer. The n-type impurity concentration of the substrate 201 is greater than the n-type impurity concentration of the first semiconductor part 211A. The first semiconductor part 211A functions as a drift layer. The second semiconductor part 211B functions as a base layer. The third semiconductor part 211C functions as a source layer. The n-type impurity concentration of the third semiconductor part 211C is greater than the n-type impurity concentration of the first semiconductor part 211A.

For example, the major element 210 has a trench gate structure. Multiple first gate electrodes 231 are arranged in the second direction X at the upper surface side of the first semiconductor region 211. The side surface of the first gate electrode 231 faces the second semiconductor part 211B. For example, two first gate electrodes 231 are positioned to be separated in the second direction X inside one trench formed in the upper surface side of the first semiconductor region 211.

The first electrode 221 is located at a second surface 201B of the substrate 201 positioned at the side opposite to the first surface 201A. The first electrode 221 is electrically connected with the substrate (the drain layer) 201. The first electrode 221 functions as a drain electrode.

The second electrode 222 is located on the upper surface of the first semiconductor region 211, and is electrically connected with the third semiconductor part 211C. The second electrode 222 functions as a source electrode. The second electrode 222 contacts the second semiconductor part 211B.

The major element 210 may further include a first insulating member 241. The first insulating member 241 is located between two first gate electrodes 231, between the first gate electrode 231 and the first semiconductor region 211, and between the first gate electrode 231 and the second electrode 222 inside one trench. The portion of the first insulating member 241 located between the first gate electrode 231 and the second semiconductor part 211B functions as a first gate insulating film. When a gate voltage that is not less than a threshold is applied to the first gate electrode 231, a channel (an inversion layer) is formed in the portion of the second semiconductor part 211B facing the first gate electrode 231. In the on-state of the major element 210, a current flows between the first electrode 221 and the second electrode 222 via the substrate (the drain layer) 201, the first semiconductor part (the drift layer) 211A, the channel, and the third semiconductor part (the source layer) 211C.

The major element 210 may further include a field plate electrode 251 located below the first gate electrode 231. The first insulating member 241 also is located between the field plate electrode 251 and the first semiconductor region 211 and between the field plate electrode 251 and the first gate electrode 231. For example, the potential (the source potential) of the second electrode 222 is applied to the field plate electrode 251. The source potential is, for example, a ground potential. The field plate electrode 251 can relax the electric field (the vertical electric field) applied in the third direction Z and can increase the breakdown voltage.

The gate driver 300 is electrically connected with the first gate electrode 231, and supplies a gate voltage V1 to the first gate electrode 231. The gate voltage V1 is, for example, a square wave.

The recording element 220 has a vertical MOSFET structure similar to that of the major element 210, and includes a substrate 202, a second semiconductor region 212, a third electrode 223, a fourth electrode 224, and at least a pair of second gate electrodes 232. One direction parallel to a first surface 202A of the substrate 202 is taken as the X-axis direction. A direction parallel to the first surface 202A and perpendicular to the X-axis direction is taken as the Y-axis direction. A direction perpendicular to the X-axis direction and the Y-axis direction is taken as the Z-axis direction. In the recording element 220, a direction along the Y-axis is taken as a fourth direction Y; a direction along the X-axis is taken as a fifth direction X; and a direction along the Z-axis is taken as a sixth direction Z. The orientations of the major element 210 and the recording element 220 are mutually-independent and are not always aligned; however, in the description, the X-axis direction, the Y-axis direction, and the Z-axis direction defined by the major element 210 and the X-axis direction, the Y-axis direction, and the Z-axis direction defined by the recording element 220 are taken to be aligned for simplicity.

The second semiconductor region 212 includes a fourth semiconductor part 212A that is located on the first surface 202A of the substrate 202 and is of the first conductivity type, a fifth semiconductor part 212B that is located on the fourth semiconductor part 212A and is of the second conductivity type, and a sixth semiconductor part 212C that is located on the fifth semiconductor part 212B and is of the first conductivity type.

Similarly to the major element 210, the substrate 202 functions as a drain layer. The n-type impurity concentration of the substrate 202 is greater than the n-type impurity concentration of the fourth semiconductor part 212A. The fourth semiconductor part 212A functions as a drift layer. The fifth semiconductor part 212B functions as a base layer. The sixth semiconductor part 212C functions as a source layer. The n-type impurity concentration of the sixth semiconductor part 212C is greater than the n-type impurity concentration of the fourth semiconductor part 212A.

At least a pair of second gate electrodes 232 is arranged in the fifth direction X at the upper surface side of the second semiconductor region 212. Among the pair of second gate electrodes 232, the side surface of one second gate electrode 232 facing the other second gate electrode 232 and the side surface of the other second gate electrode 232 facing the one second gate electrode 232 each face the fifth semiconductor part 212B.

The third electrode 223 is located at a second surface 202B of the substrate 202 positioned at the side opposite to the first surface 202A. The third electrode 223 is electrically connected with the substrate (the drain layer) 202, and functions as a drain electrode.

The fourth electrode 224 is located on the upper surface of the second semiconductor region 212, and is electrically connected with the sixth semiconductor part 212C. The fourth electrode 224 functions as a source electrode. The fourth electrode 224 contacts the fifth semiconductor part 212B.

The recording element 220 may further include a second insulating member 244. The second insulating member 244 is located between the second gate electrode 232 and the second semiconductor region 212 and between the second gate electrode 232 and the fourth electrode 224. The portion of the second insulating member 244 located between the second gate electrode 232 and the fifth semiconductor part 212B functions as a second gate insulating film.

The recording element 220 is electrically connected with the gate driver 300, and records, as continuously changing analog data, the number of times that the gate voltage is supplied to the first gate electrode 231 of the major element 210 while being enough to switch the major element 210 on.

For example, the recording element 220 includes a capacitor 502 that is charged with a charge supplied from the gate driver 300 each time the major element 210 is switched on. In the example, the capacitor 502 includes a pair of second gate electrodes 232 facing each other in the fifth direction X, and a portion (the fifth semiconductor part 212B) of the second semiconductor region 212 positioned between the pair of second gate electrodes 232.

When the capacitor 502 is charged with a charge corresponding to a gate voltage that is not less than a threshold, a channel (an inversion layer) is formed in the portion of the fifth semiconductor part 212B facing the second gate electrode 232. When a voltage is applied between the third electrode 223 and the fourth electrode 224, the magnitude of the current flowing between the third electrode 223 and the fourth electrode 224 via the substrate (the drain layer) 202, the fourth semiconductor part (the drift layer) 212A, the channel, and the sixth semiconductor part (the source layer) 212C changes according to the charge amount of the capacitor 502.

In the example shown in FIG. 1A, the recording element 220 is electrically connected with the gate driver 300 via a differential circuit 400, a rectifying circuit 600, and an integration circuit 500. As shown in FIG. 1B, the differential circuit 400 is, for example, an RC circuit including a capacitor 401 and a resistance 402.

The gate voltage (the gate signal) V1 that is output by the gate driver 300 is differentiated by the differential circuit 400. The gate voltage (the gate signal) V1 is, for example, a square wave. The differential circuit 400 outputs the time derivative (the slope) of the input signal (the voltage) V1.

The rectifying circuit 600 includes a diode 601 and a diode 602. The output of the differential circuit 400 is rectified by the diodes 601 and 602; and a voltage V2 of which the voltage of the negative side of the input voltage (the differentiated voltage of V1) is cut is output to the integration circuit 500.

The integration circuit 500 includes, for example, a resistance 501 and the capacitor 502. The charge amount of the capacitor 502, i.e., a potential V3 of the second gate electrode 232, increases each time the gate driver 300 outputs a pulse (the gate voltage V1) to switch the major element 210 on. The potential V3 is proportional to the switching count of the major element 210.

When a voltage is applied between the third electrode 223 and the fourth electrode 224 of the recording element 220, the magnitude of the current (a read current) flowing between the third electrode 223 and the fourth electrode 224 via the second semiconductor region 212 changes according to the potential V3 of the second gate electrode 232. The potential V3 of the second gate electrode 232 is known from the magnitude of the read current; and the switching count (the number of times switched on) of the major element 210 is known from the potential V3 of the second gate electrode 232. The life and/or degradation as the major element 210 is used can be predicted from the switching count of the major element 210. For example, the major element 210 can be replaced before malfunction or before performance degradation according to the usable life.

The recording element 220 records the switching count of the major element 210 as continuously changing analog data. Therefore, compared to when, for example, a CMOS circuit and a nonvolatile counter are used for digital recording, according to the embodiment, a large configuration is unnecessary, and the cost can be reduced.

It is necessary for the voltages of the third electrode 223 and fourth electrode 224 of the recording element 220 to be applied independently from the voltages of the first electrode 221 and second electrode 222 of the major element 210. Therefore, for example, the major element 210 and the recording element 220 can be formed in separate chips by using similar processes to form the major element 210 and the recording element 220 on a substrate of the same wafer or on substrates of separate wafers and then by singulating. Or, the major element 210 and the recording element 220 can be made in one chip. In such a case, it is necessary for the third electrode 223 and fourth electrode 224 of the recording element 220 to be electrically isolated from the first electrode 221 and second electrode 222 of the major element 210.

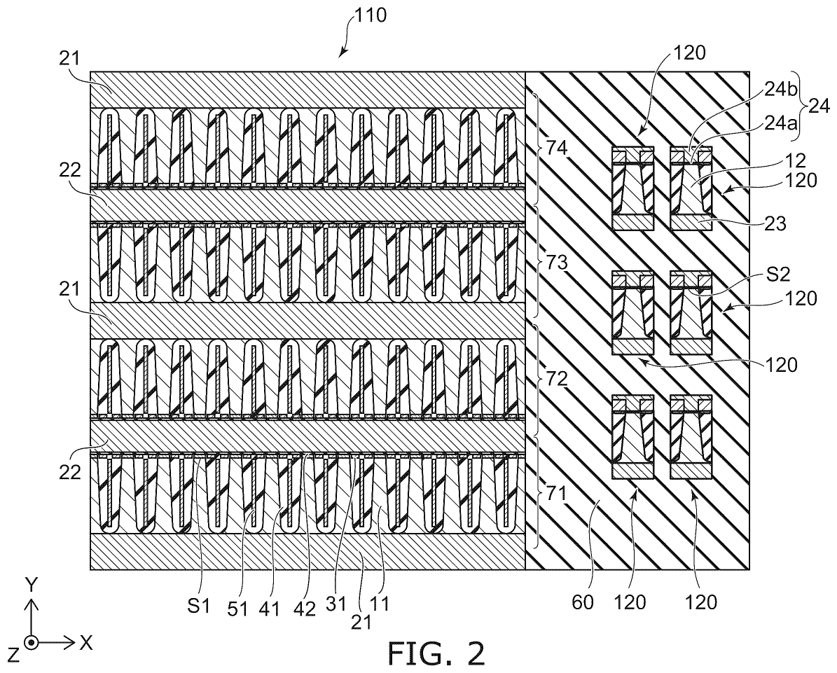

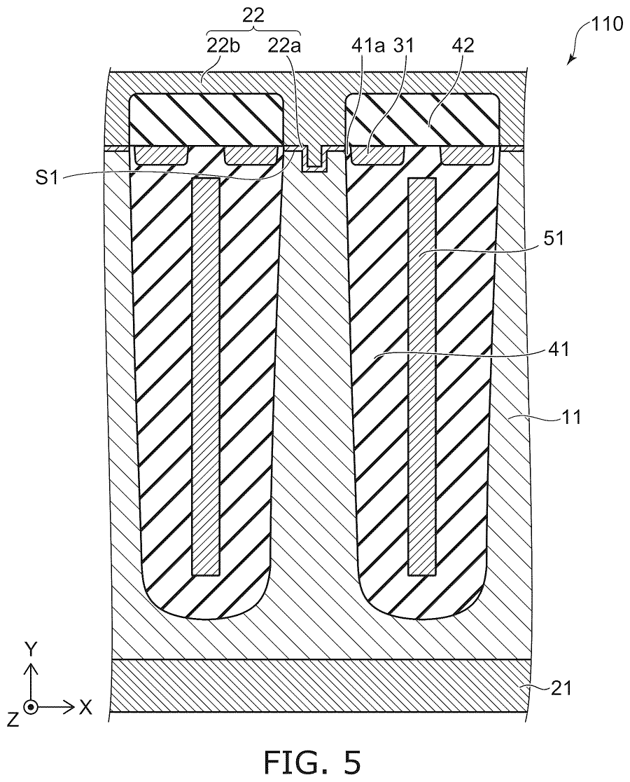

According to another example of the major element and the recording element described below with reference to FIGS. 2 to 8, the major element and the recording element that have independent electrodes can be formed easily in the same chip.

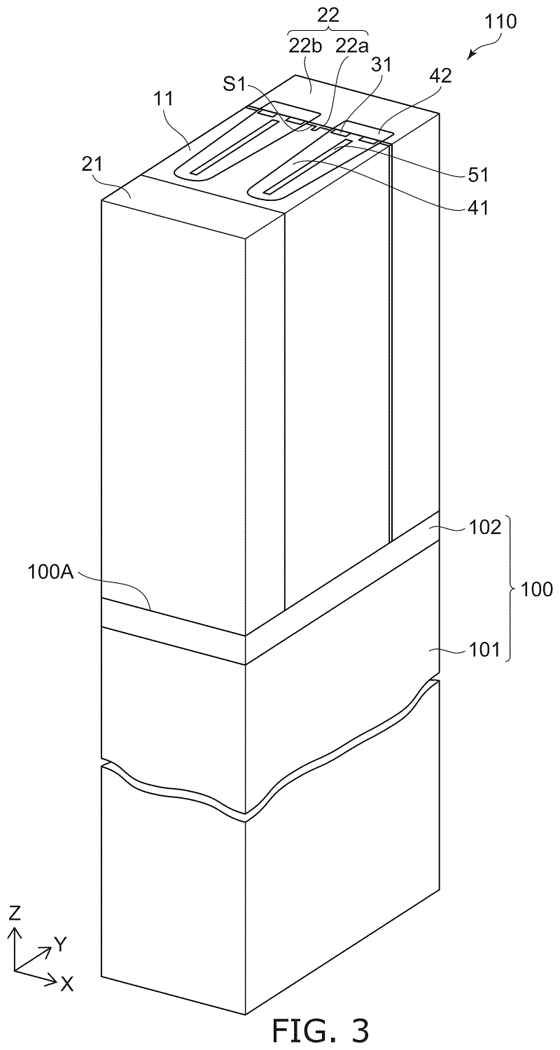

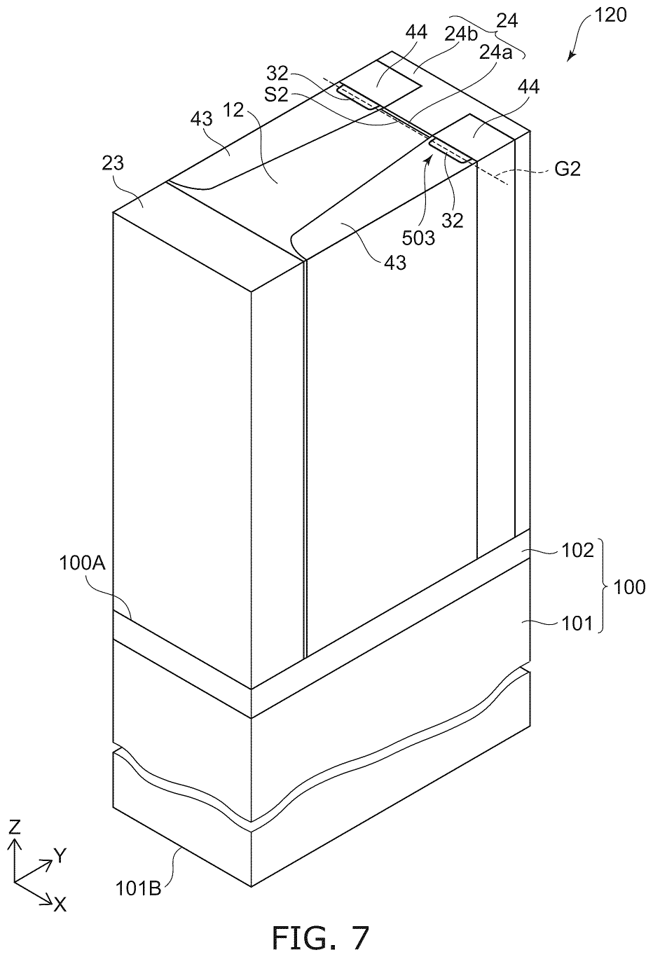

As shown in FIG. 3, the major element 110 is located on a support body 100. As shown in FIG. 7, a recording element 120 is located on the support body 100. The support body 100 includes a first surface 100A. The first direction Y and the second direction X are parallel to the first surface 100A.

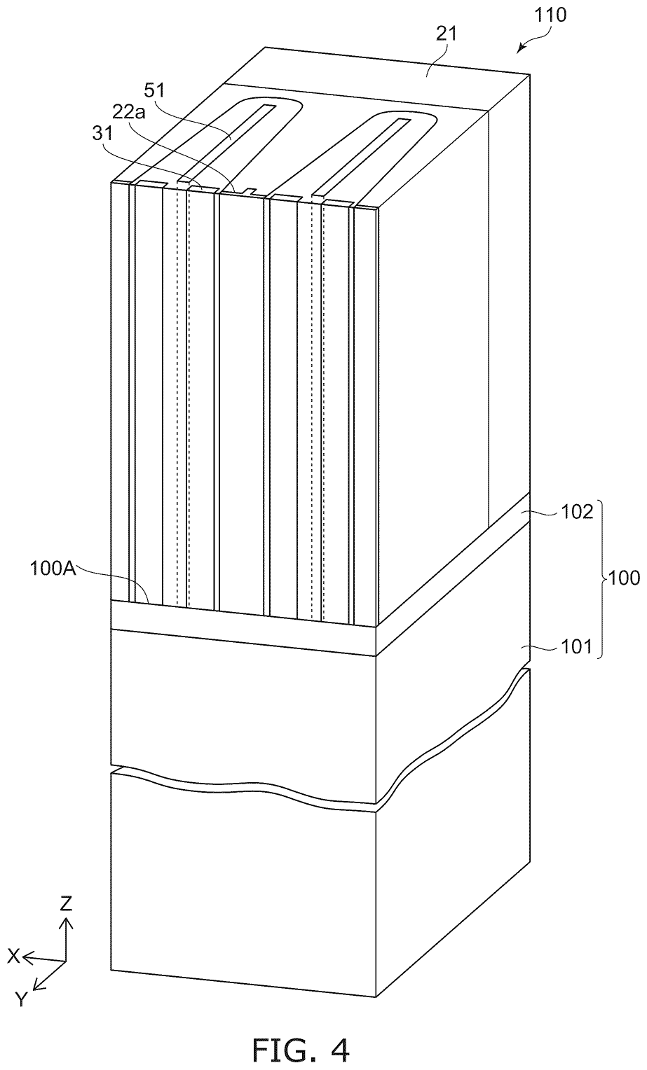

The major element 110 will now be described with reference to FIGS. 3 to 6B. FIG. 4 illustrates a state in which a second conductive part 22b and a second insulating member 42 are removed.

The support body 100 includes a substrate 101. The substrate 101 extends in the first and second directions Y and X. For example, a silicon substrate can be used as the substrate 101. The major element 110 includes a first semiconductor region 11 located on the substrate 101 in the third direction Z. The support body 100 may further include an insulating layer 102 located between the substrate 101 and the first semiconductor region 11 in the third direction Z. In the example, the upper surface of the insulating layer 102 is used as the first surface 100A of the support body 100. For example, a silicon oxide layer can be used as the insulating layer 102.

The conductivity type of the first semiconductor region 11 is the first conductivity type. The first conductivity type is one of the n- or p-type. Hereinbelow, the first conductivity type is taken to be the n-type. The first semiconductor region 11 is, for example, a silicon layer. The first semiconductor region 11 may be a silicon carbide layer or a gallium nitride layer.

The major element 110 further includes a first electrode 21 and a second electrode 22. The first electrode 21 and the second electrode 22 are positioned to be separated from each other in the first direction Y. The first semiconductor region 11 is located between the first electrode 21 and the second electrode 22 in the first direction Y, and is electrically connected with the first and second electrodes 21 and 22. The first electrode 21, the second electrode 22, and the first semiconductor region 11 extend in the third direction Z above the first surface 100A. By such a configuration, the density of the major elements 110 on the first surface 100A of the support body 100 can be increased, and, for example, the on-resistance per unit area can be reduced.

The first electrode 21 can include, for example, at least one selected from the group consisting of Al, Cu, Mo, W, Ta, Co, Ru, Ti, and Pt.

The second electrode 22 includes a first conductive part 22a and the second conductive part 22b. The first conductive part 22a contacts the first semiconductor region 11. The first semiconductor region 11 and the first conductive part 22a form a first Schottky junction S1. The first conductive part 22a is positioned between the first semiconductor region 11 and the second conductive part 22b in the first direction Y. The second conductive part 22b is electrically connected with the first conductive part 22a.

The first conductive part 22a can include, for example, at least one selected from the group consisting of Ti, W, Mo, Ta, Zr, Al, Sn, V, Re, Os, Ir, Pt, Pd, Rh, Ru, Nb, Sr, and Hf. The second conductive part 22b can include, for example, at least one selected from the group consisting of Al, Cu, Mo, W, Ta, Co, Ru, Ti, and Pt.

The major element 110 further includes a first gate electrode 31. Multiple first gate electrodes 31 are arranged in the second direction X. The first gate electrode 31 faces the first Schottky junction S1 in the second direction X. For example, polycrystalline silicon can be used as the material of the first gate electrode 31. As shown in FIG. 4, the first gate electrode 31 extends in the third direction Z. By such a configuration, transistors can be arranged with high density on the first surface 100A of the support body 100; and the channel area per unit area can be increased. For example, the on-resistance can be reduced thereby.

A potential that is higher than the potential of the second electrode 22 is applied to the first electrode 21; and a potential (e.g., the ground potential) that is lower than the potential of the first electrode 21 is applied to the second electrode 22. The first electrode 21 functions as a drain electrode; and the second electrode 22 functions as a source electrode. In the first semiconductor region 11, the n-type impurity concentration of the region contacting the first electrode 21 may be greater than the n-type impurity concentration of the other regions. The contact resistance between the first electrode 21 and the first semiconductor region 11 can be reduced thereby.

The potential of the first gate electrode 31 can control the thickness (the distance in the first direction Y) of the Schottky barrier of the first Schottky junction S1. When the Schottky barrier is thick, a current substantially does not flow between the second electrode 22 and the first semiconductor region 11. The off-state is obtained thereby. In the off-state, a depletion layer spreads through the first semiconductor region 11 from the first Schottky junction S1; and the breakdown voltage can be maintained.

By controlling the potential of the first gate electrode 31, the Schottky barrier can be thin, and, for example, a tunnel current flows between the second electrode 22 and the first semiconductor region 11. The on-state is obtained by the flow of the tunnel current.

The major element 110 may further include a field plate electrode 51, a first insulating member 41, and the second insulating member 42.

The field plate electrode 51 is located inside a trench formed in the first semiconductor region 11, and extends in the first and third directions Y and Z. For example, the field plate electrode 51 is electrically connected with the second electrode 22. The field plate electrode 51 can relax the electric field applied to the first semiconductor region 11 in the first direction Y, and can increase the breakdown voltage. For example, polycrystalline silicon can be used as the material of the field plate electrode 51.

The first insulating member 41 extends in the third direction Z, and is located between the first gate electrode 31 and the first semiconductor region 11, between the field plate electrode 51 and the first semiconductor region 11, between the first gate electrode 31 and the field plate electrode 51, and between the first gate electrodes 31 adjacent to each other in the second direction X. The first insulating member 41 includes a first gate insulating part 41a. The first gate insulating part 41a is located between the first gate electrode 31 and the first semiconductor region 11, between the first gate electrode 31 and the first Schottky junction S1, and between the first gate electrode 31 and the first conductive part 22a. The first gate electrode 31 faces the first Schottky junction S1 in the second direction X via the first gate insulating part 41a. For example, silicon oxide can be used as the material of the first insulating member 41.

The second insulating member 42 extends in the third direction Z, and is located between the first gate electrode 31 and the second conductive part 22b and between the first insulating member 41 and the second conductive part 22b. For example, silicon oxide can be used as the material of the second insulating member 42.

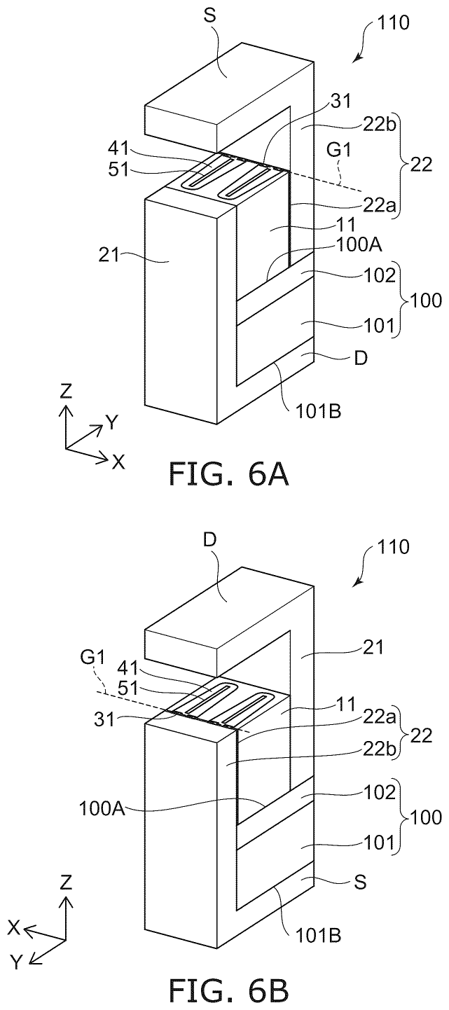

As shown in FIG. 6A, the substrate 101 includes a second surface 101B positioned at the side opposite to the first surface 100A in the third direction Z. A first wiring part D that is electrically connected with the first electrode 21 is located at the second surface 101B of the substrate 101. The first electrode 21 can be electrically connected with an external circuit via the first wiring part D. A second wiring part S can be located above the first semiconductor region 11, above the first gate electrode 31, and above the field plate electrode 51 in the third direction Z with an inter-layer insulating layer interposed. The second wiring part S is electrically connected with the second conductive part 22b of the second electrode 22. The second electrode 22 can be electrically connected with the external circuit via the second wiring part S. A first gate wiring part G1 that extends in the second direction X is located on the multiple first gate electrodes 31 arranged in the second direction X; and the multiple first gate electrodes 31 can be electrically connected with the first gate wiring part G1.

Or, as shown in FIG. 6B, the second wiring part S that is electrically connected with the second conductive part 22b of the second electrode 22 may be located at the second surface 101B of the substrate 101. The first wiring part D that is electrically connected with the first electrode 21 can be located above the first semiconductor region 11, above the first gate electrode 31, and above the field plate electrode 51 in the third direction Z with an inter-layer insulating layer interposed.

As shown in FIG. 2, multiple cell groups (first to fourth cell groups 71 to 74) are located in a region of the semiconductor device in which the major element 110 is located. In the first direction Y, the second cell group 72 is between the first cell group 71 and the fourth cell group 74; and the third cell group 73 is between the second cell group 72 and the fourth cell group 74. In each cell group, a plurality of the structure shown in FIGS. 3 to 5 above is repeatedly arranged in the second direction X.

The orientation from the first electrode 21 of the first cell group 71 toward the second electrode 22 of the first cell group 71 is the opposite of the orientation from the first electrode 21 of the second cell group 72 toward the second electrode 22 of the second cell group 72. The orientation from the first electrode 21 of the third cell group 73 toward the second electrode 22 of the third cell group 73 is the opposite of the orientation from the first electrode 21 of the fourth cell group 74 toward the second electrode 22 of the fourth cell group 74. The orientation from the first electrode 21 of the first cell group 71 toward the second electrode 22 of the first cell group 71 is the same as the orientation from the first electrode 21 of the third cell group 73 toward the second electrode 22 of the third cell group 73. The orientation from the first electrode 21 of the second cell group 72 toward the second electrode 22 of the second cell group 72 is the same as the orientation from the first electrode 21 of the fourth cell group 74 toward the second electrode 22 of the fourth cell group 74.

The first electrode 21 is shared by the second and third cell groups 72 and 73. The second electrode 22 is shared by the first and second cell groups 71 and 72. The second electrode 22 is shared by the third and fourth cell groups 73 and 74.

For example, the major element 110 can be included in a high-side switching element and a low-side switching element of a voltage converter.

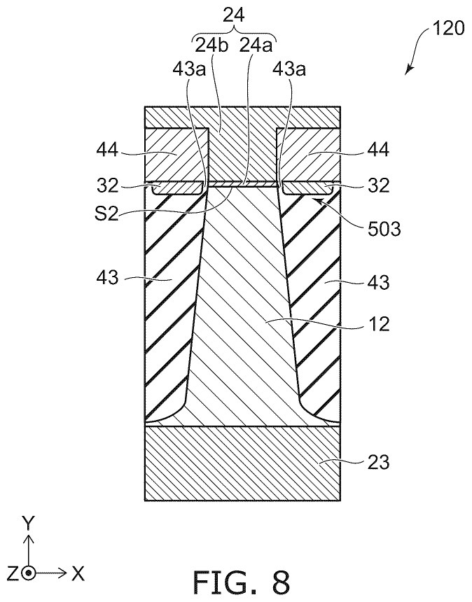

The recording element 120 will now be described with reference to FIGS. 7 and 8. In the example, the recording element 120 is located on the same substrate 101 as the major element 110; the fourth direction of the recording element 120 is aligned with the first direction Y of the major element 110; the fifth direction of the recording element 120 is aligned with the second direction X of the major element 110; and the sixth direction of the recording element 120 is aligned with the third direction Z of the major element 110.

The recording element 120 includes a second semiconductor region 12 located on the substrate 101 in the third direction (the sixth direction) Z. The conductivity type of the second semiconductor region 12 is the first conductivity type. The material of the second semiconductor region 12 can be the same as the material of the first semiconductor region 11 of the major element 110.

The recording element 120 further includes a third electrode 23 and a fourth electrode 24. The third electrode 23 and the fourth electrode 24 are positioned to be separated from each other in the first direction (the fourth direction) Y. The second semiconductor region 12 is located between the third electrode 23 and the fourth electrode 24 in the first direction (the fourth direction) Y, and is electrically connected with the third and fourth electrodes 23 and 24. The third electrode 23, the fourth electrode 24, and the second semiconductor region 12 extend in the third direction (the sixth direction) Z above the first surface 100A of the support body 100.

The fourth electrode 24 includes a third conductive part 24a and a fourth conductive part 24b. The third conductive part 24a contacts the second semiconductor region 12. The second semiconductor region 12 and the third conductive part 24a form a second Schottky junction S2. The third conductive part 24a is positioned between the second semiconductor region 12 and the fourth conductive part 24b in the first direction (the fourth direction) Y. The fourth conductive part 24b is electrically connected with the third conductive part 24a.

The material of the third electrode 23 can be the same as the material of the first electrode 21 of the major element 110. The material of the third conductive part 24a can be the same as the material of the first conductive part 22a of the major element 110. The material of the fourth conductive part 24b can be the same as the material of the second conductive part 22b of the major element 110.

The recording element 120 further includes a second gate electrode 32. Multiple second gate electrodes 32 are arranged in the second direction (the fifth direction) X. The second gate electrode 32 faces the second Schottky junction S2 in the second direction (the fifth direction) X. The second gate electrode 32 extends in the third direction (the sixth direction) Z. The material of the second gate electrode 32 can be the same as the material of the first gate electrode 31 of the major element 110.

The potential of the second gate electrode 32 can control the thickness (the distance in the first direction (the fourth direction) Y) of the Schottky barrier of the second Schottky junction S2. By controlling the potential of the second gate electrode 32, the Schottky barrier can be thin, and, for example, a tunnel current flows between the fourth electrode 24 and the second semiconductor region 12. As a result, a current flows between the third electrode 23 and the fourth electrode 24 via the second semiconductor region 12.

The recording element 120 may further include a third insulating member 43 and a fourth insulating member 44.

The third insulating member 43 is located between the second gate electrode 32 and the second semiconductor region 12, and extends in the third direction (the sixth direction) Z. As shown in FIG. 8, the third insulating member 43 includes a second gate insulating part 43a. The second gate insulating part 43a is located between the second gate electrode 32 and the second semiconductor region 12, between the second gate electrode 32 and the second Schottky junction S2, and between the second gate electrode 32 and the third conductive part 24a. The second gate electrode 32 faces the second Schottky junction S2 in the second direction (the fifth direction) X via the second gate insulating part 43a. The material of the third insulating member 43 can be the same as the material of the first insulating member 41 of the major element 110.

The fourth insulating member 44 extends in the third direction (the sixth direction) Z, and is located between the second gate electrode 32 and the fourth conductive part 24b and between the third insulating member 43 and the fourth conductive part 24b. The material of the fourth insulating member 44 can be the same as the material of the second insulating member 42 of the major element 110.

A semiconductor device of the embodiment can be configured by replacing the major element 210 shown in FIGS. 1A and 1B with the major element 110 shown in FIGS. 3 to 6B, and by replacing the recording element 220 shown in FIGS. 1A and 1B with the recording element 120 shown in FIGS. 7 and 8.

In other words, the gate driver 300 is electrically connected with the first gate electrode 31 of the major element 110, and supplies the gate voltage V1 to the first gate electrode 31.

The recording element 120 is electrically connected with the gate driver 300 via the differential circuit 400, the rectifying circuit 600 (the diode 601 and the diode 602), and the integration circuit 500.

The recording element 120 is electrically connected with the gate driver 300, and records, as continuously changing analog data, the number of times that the gate voltage is supplied to the first gate electrode 31 of the major element 110 while being enough to switch the major element 110 on.

For example, the recording element 120 includes a capacitor 503 that is charged with the charge supplied from the gate driver 300 each time the major element 110 is switched on. In the example shown in FIGS. 7 and 8, the capacitor 503 includes a pair of second gate electrodes 32 facing each other in the second direction (the fifth direction) X, and a portion of the second semiconductor region 12 positioned between the pair of second gate electrodes 32.

When the capacitor 503 is charged with a charge corresponding to a gate voltage that is not less than a threshold, the Schottky barrier of the second Schottky junction S2 becomes thin. When a voltage is applied between the third electrode 23 and the fourth electrode 24, the magnitude of the current (the read current) flowing between the third electrode 23 and the fourth electrode 24 changes according to the charge amount of the capacitor 503. The potential of the second gate electrode 32 of the recording element 120 is known from the magnitude of the read current; and the switching count (the number of times switched on) of the major element 110 is known from the potential of the second gate electrode 32. The life and degradation as the major element 110 is used can be predicted from the switching count of the major element 110.

In the example as well, the recording element 120 records the switching count of the major element 110 as continuously changing analog data; therefore, a large configuration is unnecessary, and the cost can be reduced.

According to the major element 110 and the recording element 120 shown in FIGS. 2 to 8, the major element 110 and the recording element 120 can be formed using the same processes by only changing the mask pattern between the major element 110 and the recording element 120 when etching and forming films for forming the components of the major element 110 and the recording element 120. For example, the first semiconductor region 11 and the second semiconductor region 12 can be formed on the same substrate 101; and the major element 110 and the recording element 120 can be formed as-is as one chip. As a result, a power semiconductor device in which the recording element 120 is inexpensively embedded can be made in one chip. When the major element 110 and the recording element 120 are made in one chip, the parasitic inductance of the wiring parts electrically connecting between the major element 110 and the recording element 120 can be reduced.

Multiple recording elements 120 may be embedded in the semiconductor device. As shown in FIG. 2, a fifth insulating member 60 can be located between the major element 110 and the recording element 120 on the substrate 101. The fifth insulating member 60 also can be located between the multiple recording elements 120. For example, silicon oxide can be used as the material of the fifth insulating member 60.

Or, after forming the first semiconductor region 11 and the second semiconductor region 12 on the same substrate 101, the chip of the major element 110 and the chip of the recording element 120 may be separated. In such a case, the chip of the major element 110 and the chip of the recording element 120 can be mounted on the same wiring substrate and packaged. In such a case, the wiring substrate can be included as the support body supporting the major element 110 and the recording element 120.

The third electrode 23 of the recording element 120 can be electrically connected with an external circuit via a third wiring part located above the second semiconductor region 12 in the third direction (the sixth direction) Z. The fourth electrode 24 can be electrically connected with the external circuit via a fourth wiring part located above the second semiconductor region 12 in the third direction (the sixth direction) Z. The second gate electrode 32 can be electrically connected with a second gate wiring part G2 that is located on the second gate electrode 32 and extends in the second direction (the fifth direction) X.

It is favorable for the third and fourth electrodes 23 and 24 of the recording element 120 to be positioned on the first surface 100A, but not to be positioned at the second surface 101B. Leakage current between the first wiring part D or the second wiring part S of the major element 110 on the second surface 101B of the substrate 101 described above and the major electrodes (the third electrode 23 and the fourth electrode 24) of the recording element 120 can be suppressed thereby.

The voltage that is applied between the first electrode 21 and the second electrode 22 of the major element 110 is greater than the voltage applied between the third electrode 23 and the fourth electrode 24 of the recording element 120. For example, the voltage that is applied between the first electrode 21 and the second electrode 22 of the major element 110 is not less than 100 V; and the voltage that is applied between the third electrode 23 and the fourth electrode 24 of the recording element 120 is about several V. Therefore, because the breakdown voltage of the major element 110 is high, it is favorable for the thickness in the first direction Y of the first semiconductor region 11 of the major element 110 to be greater than the thickness in the first direction (the fourth direction) Y of the second semiconductor region 12 of the recording element 120.

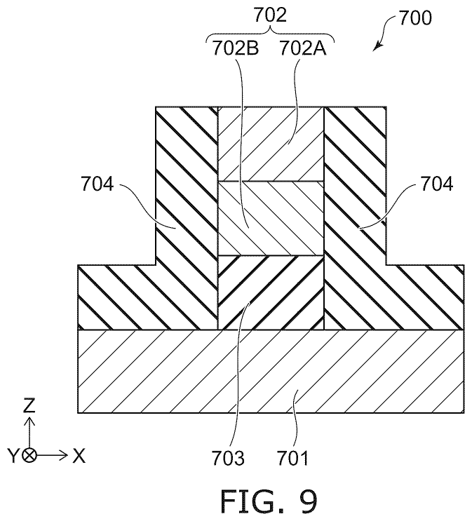

As shown in FIG. 9, for example, resistance random access memory can be used as a recording element 700. The recording element 700 includes a variable resistance layer 703 of which the resistance changes according to the charge supplied from the gate driver each time the major element is switched on.

The variable resistance layer 703 is located between a fifth electrode 701 and a sixth electrode 702 in the third direction Z. The sixth electrode 702 includes a first part 702A and a second part 702B. The second part 702B is located between the first part 702A and the variable resistance layer 703. The fifth electrode 701 extends in the second direction X; and the first part 702A of the sixth electrode 702 extends in the first direction Y. The second part 702B and the variable resistance layer 703 are provided in a columnar shape at the crossing portion between the fifth electrode 701 and the first part 702A of the sixth electrode 702. The side surface of the sixth electrode 702, the side surface of the variable resistance layer 703, and the upper surface of the fifth electrode 701 are covered with an insulating member 704.

For example, titanium nitride can be used as the material of the fifth electrode 701 and the first part 702A of the sixth electrode 702. For example, titanium can be used as the material of the second part 702B of the sixth electrode 702. For example, silicon oxide can be used as the material of the variable resistance layer 703. For example, silicon nitride can be used as the material of the insulating member 704.

The gate voltage (the gate signal) that is output by the gate driver is applied to the fifth and sixth electrodes 701 and 702. The resistance of the variable resistance layer 703 increases (or decreases) each time the gate driver outputs a pulse (the gate voltage) to switch the major element on. The resistance of the variable resistance layer 703 is proportional to the switching count of the major element.

When a voltage is applied between the fifth electrode 701 and the sixth electrode 702 when reading the resistance of the variable resistance layer 703, the magnitude of the current (the read current) flowing between the fifth electrode 701 and the sixth electrode 702 changes according to the resistance of the variable resistance layer 703. The resistance of the variable resistance layer 703 is known from the magnitude of the read current; and the switching count (the number of times switched on) of the major element is known from the resistance of the variable resistance layer 703.

In the recording element 700 as well, the switching count of the major element is recorded as continuously changing analog data; therefore, a large configuration is unnecessary, and the cost can be reduced.

For example, the major element 110 and the recording element 700 can be made in one chip by forming the recording element 700 on the major element 110 shown in FIGS. 2 to 6B with an inter-layer insulating layer interposed.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A semiconductor device, comprising:
a major element including a first semiconductor region, a first electrode, a second electrode, a first gate electrode, and a first insulating member, the first insulating member being positioned between the first gate electrode and the first semiconductor region, a gate voltage of the first gate electrode controlling a current flowing between the first electrode and the second electrode via the first semiconductor region;
a gate driver supplying the gate voltage to the first gate electrode; and
a recording element electrically connected with the gate driver, the recording element recording, as continuously changing analog data, a number of times that the gate voltage is supplied to the first gate electrode while being enough to switch the major element on.

2. The device according to claim 1, wherein
the recording element includes a capacitor, and
the capacitor is charged with a charge supplied from the gate driver each time the major element is switched on.

3. The device according to claim 1, wherein
the recording element includes a second semiconductor region, a third electrode, a fourth electrode, a second gate electrode, and a second insulating member, and
the second insulating member is positioned between the second gate electrode and the second semiconductor region.

4. The device according to claim 3, further comprising:
a support body including a first surface,
the support body supporting the major element and the recording element,
the first and second electrodes of the major element being positioned to be separated from each other in a first direction,
the first direction being along the first surface,
the first semiconductor region of the major element being located between the first electrode and the second electrode in the first direction,
the first semiconductor region of the major element forming a first Schottky junction with the second electrode,
the first gate electrode of the major element facing the first Schottky junction in a second direction,
the second direction being along the first surface and crossing the first direction,
the third and fourth electrodes of the recording element being positioned to be separated from each other in a fourth direction,
the fourth direction being along the first surface,
the second semiconductor region of the recording element being located between the third electrode and the fourth electrode in the fourth direction,
the second semiconductor region of the recording element forming a second Schottky junction with the fourth electrode,
the second gate electrode of the recording element facing the second Schottky junction in a fifth direction,
the fifth direction being along the first surface and crossing the fourth direction.

5. The device according to claim 4, wherein
the support body includes a substrate, and
the first semiconductor region and the second semiconductor region each are located on the substrate.

6. The device according to claim 5, wherein
the substrate includes a second surface positioned at a side opposite to the first surface in a third direction crossing the first and second directions, and
the third and fourth electrodes of the recording element are positioned on the first surface.

7. The device according to claim 1, wherein
the recording element includes a variable resistance layer, and
a resistance of the variable resistance layer changes according to a charge supplied from the gate driver each time the major element is switched on.

8. The device according to claim 6, further comprising:
a differential circuit connected between the gate driver and the second gate electrode.

9. The device according to claim 8, further comprising:
an integration circuit connected between the gate driver and the second gate electrode.

10. The device according to claim 9, further comprising:
a diode connected in series between the gate driver and the second gate electrode.

11. A semiconductor device, comprising:
a major element including a first semiconductor region, a first electrode, a second electrode, a first gate electrode, and a first insulating member, the first insulating member being positioned between the first gate electrode and the first semiconductor region;
a gate driver connected to the first gate electrode;
a recording element including a second semiconductor region, a third electrode, a fourth electrode, at least a pair of second gate electrodes, and a second insulating member, the second insulating member being positioned between the second gate electrode and the second semiconductor region;
a capacitor;
a diode;
a first resistance; and
a second resistance,
the capacitor, the diode, and the first resistance being connected in series between the gate driver and the second gate electrode,
one end portion of the second resistance being connected to one end of the capacitor.
